(19) United States
(12) Patent Application Publication
(10) Pub. No.: US 2025/0126933 A1
(43) Pub. Date: Apr. 17, 2025

(54) LIGHT EMITTING DEVICE AND LIGHT EMITTING DEVICE SUBSTRATE

(71) Applicant: PlayNitride Display Co., Ltd., MiaoLi County (TW)

(72) Inventors: Yi-Min Su, MiaoLi County (TW); Chung-Yu Chang, MiaoLi County (TW); Yi-Ting Chen, MiaoLi County (TW); Ching-Liang Lin, MiaoLi County (TW)

(73) Assignee: PlayNitride Display Co., Ltd., MiaoLi County (TW)

(21) Appl. No.: 18/507,103

(22) Filed: Nov. 13, 2023

(30) Foreign Application Priority Data
Oct. 17, 2023 (TW) 112139484

(51) Int. Cl. H01L 33/20; H01L 25/075

(52) U.S. Cl. CPC H10H 20/819; H01L 25/0753

(57) ABSTRACT

A light emitting device including an epitaxial structure and a plurality of surface microstructures is provided. The epitaxial structure has a light emitting surface and a surrounding wall surface. The surrounding wall surface surrounds and is connected to the light emitting surface. The plurality of surface microstructures are separately arranged on the light emitting surface along a plurality of directions. The plurality of directions are not perpendicular to the surrounding wall surface. A light emitting device substrate including a plurality of the light emitting device is also provided.

### CROSS-REFERENCE TO RELATED APPLICATION

This application claims the priority benefit of Taiwan application serial no. 112139484, filed on Oct. 17, 2023. The entirety of the above-mentioned patent application is hereby incorporated by reference herein and made a part of this specification.

### BACKGROUND OF THE INVENTION

### Field of the Invention

The invention relates to a device and a device substrate, and in particular to a light emitting device and a light emitting device substrate.

### Description of Related Art

In addition to the advantages of low energy consumption and long material life, micro LED displays also have excellent optical performance, such as high color saturation, fast response speed, and high contrast. Therefore, in recent years, micro LED displays have gradually attracted the investment attention of major technology companies. In the production process of micro LEDs, since the lattice constant of epitaxial materials (such as gallium nitride) does not match the lattice constant of the substrate for growing crystals (such as sapphire substrate), threading dislocation defects are readily formed in the epitaxial structure layer, and the distribution positions of such defects are all random.

In order to solve this issue, a method using patterned-sapphire substrate (PSS) for epitaxy is proposed. The PSS structure may reduce the number of the defects via patterned protrusions on the substrate, and the micro LEDs formed by this method copy the pattern profile of the PSS at a side surface connected to the PSS. After the PSS is removed, a microstructure corresponding to the PSS pattern profile is generated at the surface of the LED. However, in the subsequent cutting process of the micro LEDs, it is practically impossible to incorporate the cut microstructure shape into the design basis of the exposure pattern. This results in each of the cut micro LEDs having random and different microstructure cut sections in response to the exposure pattern. Since the surface microstructures of micro LEDs affect the light extraction efficiency thereof and/or light scattering mode, the cross sectional differences destroy the overall light emission uniformity of the micro LEDs.

### SUMMARY OF THE INVENTION

The invention provides a light emitting device and a light emitting device substrate having better light emission uniformity.

A light emitting device of the invention includes an epitaxial structure and a plurality of surface microstructures. The epitaxial structure has a light emitting surface and a surrounding wall surface. The surrounding wall surface surrounds and is connected to the light emitting surface. The plurality of surface microstructures are separately arranged on the light emitting surface along a plurality of directions, and the directions are not perpendicular to the surrounding wall surface.

A light emitting device substrate of the invention includes a carrier board and a plurality of light emitting devices. The light emitting devices are disposed on the carrier board and each include an epitaxial structure and a plurality of surface microstructures.

The epitaxial structure has a light emitting surface. The plurality of surface microstructures are separately arranged on the light emitting surface along a plurality of directions. An orthographic projection of the plurality of epitaxial structures of the plurality of light emitting devices on the carrier board defines a plurality of isolation area patterns of the carrier board. The plurality of directions are not perpendicular to an extending direction of each of the isolation area patterns.

Based on the above, in the light emitting device substrate of an embodiment of the invention, none of the plurality of arrangement directions of the plurality of surface microstructures on the epitaxial structure of each of the light emitting devices is perpendicular to the surrounding wall surface of the epitaxial structure. Therefore, the light emission uniformity of the light emitting device and the overall light emission uniformity among the plurality of light emitting devices on the light emitting device substrate may be effectively improved.

In order to make the aforementioned features and advantages of the disclosure more comprehensible, embodiments accompanied with figures are described in detail below.

### BRIEF DESCRIPTION OF THE DRAWINGS

FIG. 1 is a schematic cross sectional view of a light emitting device according to an embodiment of the invention.

FIG. 2 is a schematic three dimensional view of the epitaxial structure of FIG. 1.

FIG. 3A and FIG. 3B are schematic three dimensional views of an epitaxial structure according to other modified embodiments of the invention.

FIG. 4A and FIG. 4B are schematic cross sectional views of the cut sections of a light emitting device of the invention at different positions.

FIG. 5 is a schematic three dimensional view of a light emitting device substrate according to an embodiment of the invention.

### DESCRIPTION OF THE EMBODIMENTS

Reference will now be made in detail to the exemplary embodiments of the invention, and examples of the exemplary embodiments are illustrated in the accompanying drawings. Wherever possible, the same reference numerals are used in the figures and the descriptions to refer to the same or similar portions.

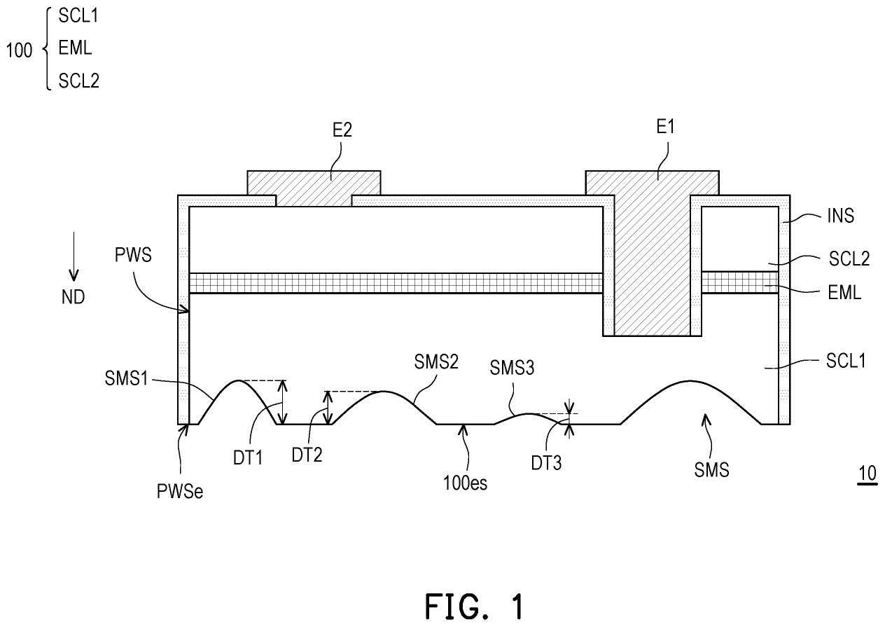

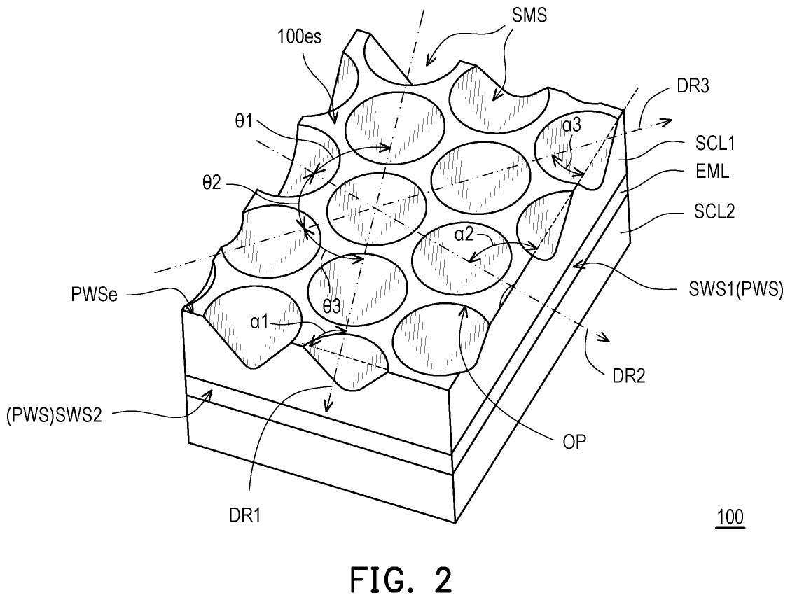

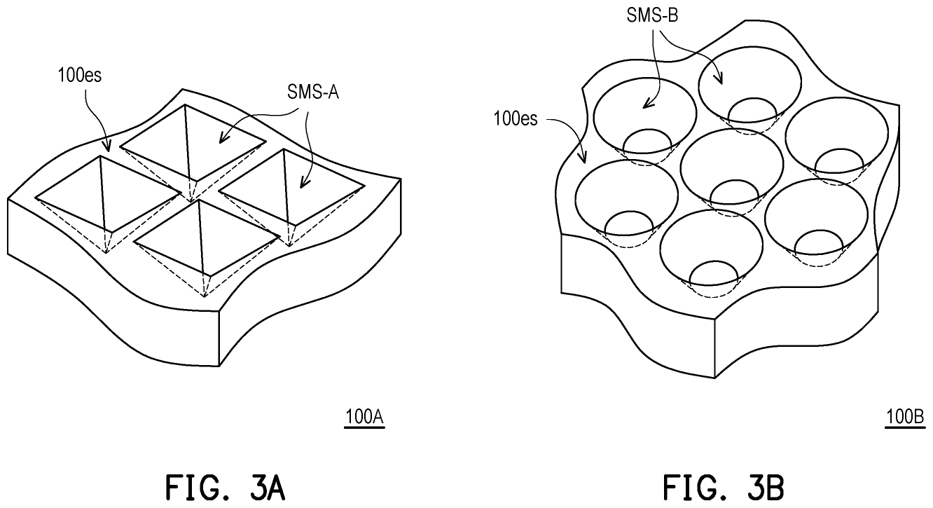

FIG. 1 is a schematic cross sectional view of a light emitting device according to an embodiment of the invention. FIG. 2 is a schematic three dimensional view of the epitaxial structure of FIG. 1. FIG. 3A and FIG. 3B are schematic three dimensional views of an epitaxial structure according to other modified embodiments of the invention.

Referring to FIG. 1 and FIG. 2, a light emitting device 10 includes an epitaxial structure 100 and a plurality of surface microstructures SMS. The epitaxial structure 100 has a light emitting surface 100es and a surrounding wall surface PWS. The surrounding wall surface PWS surrounds and is connected to the light emitting surface 100es. The epitaxial structure 100 includes, for example, a light emitting layer EML and a first type semiconductor layer SCL1 and a second type semiconductor layer SCL2 disposed at two opposite sides of the light emitting layer EML. The light emitting device 10 is provided with a first electrode E1 and a second electrode E2 at a side of the epitaxial structure 100 facing away from the light emitting surface 100es. The first electrode E1 is electrically connected to the first type semiconductor layer SCL1. The second electrode E2 is electrically connected to the second type semiconductor layer SCL2.

Moreover, the light emitting device 10 may further include an insulating layer INS covering the surrounding wall surface PWS of the epitaxial structure 100 and extended between the first electrode E1 and the second type semiconductor layer SCL2 and between the first electrode E1 and the light emitting layer EML, but the invention is not limited thereto.

Furthermore, the plurality of surface microstructures SMS are separately arranged on the light emitting surface 100es along at least one direction. For example, in the present embodiment, the surface microstructures SMS may be a plurality of micro grooves that are concave from the light emitting surface 100es and each are conical, but are not limited thereto.

In another modified embodiment, a plurality of surface microstructures SMS-A of an epitaxial structure 100A may also be a plurality of micro grooves that are recessed from the light emitting surface 100es and are each pyramid shaped, wherein the epitaxial structure 100A defines an opening profile of each of the micro grooves, such as a rectangle (as shown in FIG. 3A), a triangle, or a polygon. In other embodiments not shown, the pyramid vertex in each of the micro grooves may also not be limited to one. For example, the micro grooves may be polygonal pyramids, or prisms or cylinders without vertices. In yet another modified embodiment, a plurality of surface microstructures SMS-B of an epitaxial structure 100B may also be a plurality of micro grooves that are recessed from the light emitting surface 100es and are each in the shape of a boss (as shown in FIG. 3B), wherein the epitaxial structure 100B defines an opening profile of each of the micro grooves, for example, a circle, and the bottom plane of the plurality of boss shaped micro grooves may be non-parallel to the light emitting surface 100es.

In the present embodiment, the light emitting surface 100es of the epitaxial structure 100 defines the opening OP profile of each of the surface microstructures SMS to be the same, and the depth of each of the surface microstructures SMS along a normal direction ND of the light emitting surface 100es (that is, the distance from the cone tip to the light emitting surface 100es) is the same.

In the present embodiment, the plurality of surface microstructures SMS are separately arranged in a hexagonal close packing (HCP) manner, for example. For example, the surface microstructures SMS may be arranged along a first direction DR1, a second direction DR2, and a third direction DR3 respectively. An included angle θ1 between the first direction DR1 and the second direction DR2, an included angle θ2 between the second direction DR2 and the third direction DR3, and an included angle θ3 between the third direction DR3 and the first direction DR1 are all 60 degrees, but not limited thereto.

In the present embodiment, the surrounding wall surface PWS of the epitaxial structure 100 has an edge PWSe connected to the light emitting surface 100es, and the outline of the edge PWSe is, for example, a rectangle. From another perspective, the surrounding wall surface PWS of the epitaxial structure 100 may include four sidewall surfaces, and any two adjacent ones in the four sidewall surfaces are perpendicular to each other. For example, a sidewall surface SWS1 and a sidewall surface SWS2 of the surrounding wall surface PWS are connected to each other and are perpendicular to each other (as shown in FIG. 2).

It is particularly noted that the plurality of arrangement directions of the plurality of surface microstructures SMS, such as the first direction DR1, the second direction DR2, and the third direction DR3, are all not perpendicular to the surrounding wall surface PWS of the epitaxial structure 100. More specifically, the included angle between each of the arrangement directions and any sidewall surface of the surrounding wall surface PWS may be between 5 degrees and 25 degrees, between 35 degrees and 55 degrees, or between 65 degrees and 85 degrees.

For example, an included angle α1 between the first direction DR1 and the sidewall surface SWS2 may be between 65 degrees and 85 degrees, an included angle α2 between the second direction DR2 and the sidewall surface SWS1 may be between 65 degrees and 85 degrees, preferably 75 degrees, for example. An included angle α3 between the third direction DR3 and the sidewall surface SWS1 or the sidewall surface SWS2 may be between 35 degrees and 55 degrees, preferably 45 degrees, for example. Alternatively, the included angle between the first direction DR1 and the sidewall surface SWS1 may be between 5 degrees and 25 degrees, the included angle between the second direction DR2 and the sidewall surface SWS2 may be between 5 degrees and 25 degrees, preferably 15 degrees, for example.

Via the included angle configuration relationship between the above arrangement directions and the sidewall surface, it may be ensured that the cutting shape of the plurality of surface microstructure SMS at the cut section (i.e., the sidewall surface) of the epitaxial structure 100 exhibits irregularities in size or depth. It should be noted that the preferred angle design corresponding to different included angle ranges here corresponds to the middle value of the included angle range (such as 15 degrees, 45 degrees, or 75 degrees). Specifically, in the hexagonal close packing arrangement, the included angle relationship between the arrangement direction and the sidewall surface exhibits a regularity of one cycle every 30 degrees. Therefore, for the cut sections of the epitaxial structure 100, in the cycle period in which the included angle between each two cut sections and the surface microstructure SMS is 0 degrees, selecting a range near the middle value thereof (i.e., 15 degrees, 45 degrees, or 75 degrees) may ensure that the profiles of all epitaxial structures 100 on all cut sections show irregularities and have a surface microstructure SMS with a more similar light emission effect, and this irregularity is not destroyed due to the precision error of the cutting process.

For example, it may be seen from the cross sectional view of FIG. 1 or the sidewall surface SWS1 of FIG. 2 that four surface microstructures of different sizes and depths may be revealed on a cut section (i.e., one sidewall surface) of the epitaxial structure 100. In particular, the first surface microstructure SMS1, the second surface microstructure SMS2, and the third surface microstructure SMS3 respectively have a first maximum depth DT1, a second maximum depth DT2, and a third maximum depth DT3 along the normal direction ND of the light emitting surface 100es, and the first maximum depth DT1, the second maximum depth DT2, and the third maximum depth DT3 are different from each other.

More specifically, among the plurality of surface microstructures SMS exposed in any cut section of the epitaxial structure 100, at least three surface microstructures SMS have different maximum depths on the cut section.

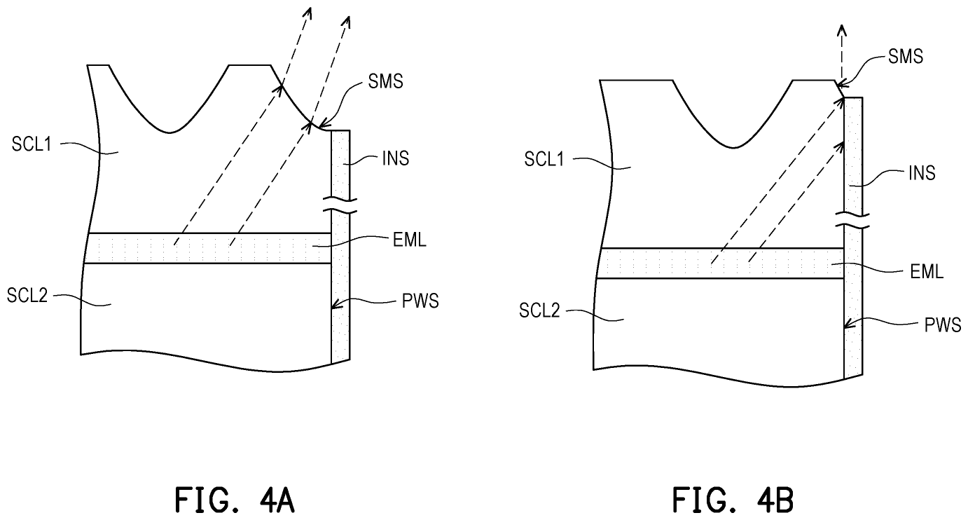

First, it should be explained that if the cut section of the epitaxial structure is parallel or perpendicular to the arrangement direction of the plurality of surface microstructures SMS, there are at most two maximum depths of the surface microstructures SMS revealed by the epitaxial structure at any cut section. For example, if the epitaxial structure is cut along the first direction DR1, there are two states of the cut section. One is to reveal a surface microstructure SMS having only a single maximum depth (e.g. cut on DR1 line of FIG. 2); and the other one is that the cut section is located exactly near the tangent line of the surface microstructures SMS of two adjacent columns. At this time, the surface microstructures SMS from two sides of the cut section are exposed at the same time, and the maximum depths of the surface microstructures SMS at two sides may be different, but the depths are extremely small. FIG. 4A and FIG. 4B are respectively a schematic cross sectional view in which the cut section is located on the DR1 line, and a schematic cross sectional view in which the cut section is located near the tangent line of two adjacent columns of surface microstructures SMS. It may be seen from FIG. 4A and FIG. 4B that the position of the cut section significantly changes the shape of the exposed surface microstructures SMS. That is, in FIG. 4A, the exposed surface microstructures SMS have the largest area and are densely distributed; while in FIG. 4B, since the cut section is exactly located at the tangent line of two adjacent columns of surface microstructures SMS, the area of the exposed surface microstructures SMS thereof is almost zero. The difference causes the incident angle of the light emitted from the light emitting layer EML to the cut section to be enlarged in FIG. 4B, causing the proportion of light that undergoes total reflection (toward the light emitting surface) to become higher. Therefore, the light pattern is more concentrated than that of the epitaxial structure 100 of FIG. 4A.

In other words, if the epitaxial structure is cut parallel or perpendicular to the arrangement direction of the plurality of surface microstructures SMS, the plurality of cut epitaxial structures have significant differences in light emission brightness, thus affecting the light emission uniformity between different light emitting devices. As the size of the light emitting device gradually shrinks, the brightness difference caused by the uneven surface microstructures of the cut section is more significant. In addition, as the exposure pattern of the lithography process becomes denser, the occurrence frequency of the above phenomenon on the semiconductor wafer is also increased.

Referring to FIG. 2, since the cut section of the epitaxial structure 100 of the present embodiment is neither parallel nor perpendicular to the arrangement direction of the plurality of surface microstructures SMS, the plurality of surface microstructures SMS exposed on any cut section of the epitaxial structure 100 may have at least three maximum depths. More specifically, the depth diversity of the surface microstructures SMS revealed on the cut section of the epitaxial structure 100 of the present embodiment is better, and such a structure appears uniformly on all cut sections of each of the epitaxial structures 100, so the difference in light emission brightness between the plurality of cut epitaxial structures 100 may be significantly reduced.

It should be noted that in the drawings, the number of surface microstructures SMS on the light emitting surface 100es of the epitaxial structure 100 is only used for exemplary illustration, and does not mean that the invention is limited thereto. In other embodiments, the number of surface microstructures SMS of the epitaxial structure may be adjusted according to different product requirements or designs.

Furthermore, the specific angles illustrated in the embodiments are not intended to limit the meaning of the term “not vertical” of the invention. In detail, since the size of the surface microstructures SMS is generally very small, the sidewall surface of each of the epitaxial structures 100B may correspond to many surface microstructures SMS. In such a state, only a smaller angular deviation, such as 87 degrees to 89 degrees (i.e., a deviation of 1 degree to 3 degrees) is needed to allow the surface microstructures SMS to present a variety of depths, and each sidewall surface exhibits this feature consistently.

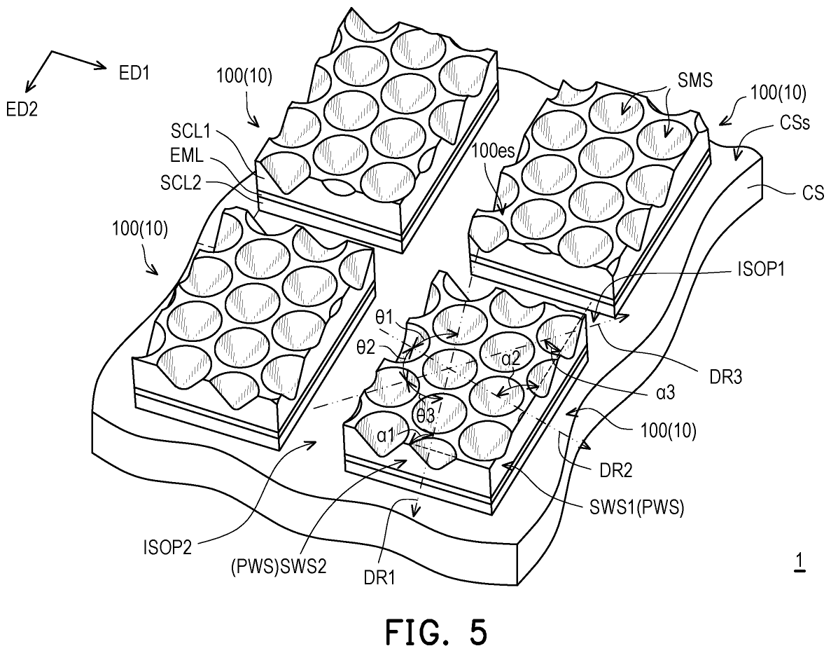

FIG. 5 is a schematic three dimensional view of a light emitting device substrate according to an embodiment of the invention. It should be noted that for the sake of clear presentation, only the epitaxial structure 100 of the light emitting device 10 in FIG. 5 is shown.

Referring to FIG. 5, the light emitting device substrate 1 includes a carrier board CS and a plurality of light emitting devices 10 disposed on the carrier board CS. Since the light emitting device 10 of the present embodiment is similar to the light emitting device 10 of FIG. 1, please refer to the relevant paragraphs of the foregoing embodiments for the detailed structural features and configuration relationships thereof, which are not described again here.

In the present embodiment, the orthographic projection of the plurality of epitaxial structures 100 of the plurality of light emitting devices 10 on a surface CSs of the carrier board CS defines a plurality of isolation area patterns of the carrier board CS. More specifically, the surrounding wall surface PWS of each of the epitaxial structures 100 defines the isolation area patterns, such as a plurality of first isolation area patterns ISOP1 and a plurality of second isolation area patterns ISOP2. For example, the arrangement direction of the plurality of first isolation area patterns ISOP1 is perpendicular to the arrangement direction of the plurality of second isolation area patterns ISOP2, and an extending direction ED1 of the first isolation area patterns ISOP1 is perpendicular to an extending direction ED2 of the second isolation area patterns ISOP2.

Special attention should be paid to the arrangement direction of the plurality of surface microstructures SMS on the epitaxial structure 100 of each of the light emitting devices 10. For example, none of the first direction DR1, the second direction DR2, and the third direction DR3 is perpendicular to any isolation area pattern. For example, in the present embodiment, the plurality of epitaxial structures 100 on the carrier board CS are obtained by etching the epitaxial structure layer formed by the same epitaxial process, wherein the etching step adopts a photolithography etching technique, for example, and none of the arrangement directions of the used photomask patterns (for example, a plurality of light shielding patterns or a plurality of light transmitting patterns of the plurality of epitaxial structures 100 are respectively defined) is parallel or perpendicular to any of the arrangement directions of the plurality of surface microstructures SMS on the epitaxial structure 100.

Via such a design, the maximum depth diversity of the surface microstructures SMS revealed on any cut section of the plurality of epitaxial structures 100 produced after etching may be improved. That is, the configuration distribution of each of the epitaxial structures 100 on the cut section is more randomly scattered. Therefore, the difference in light emission brightness among the plurality of light emitting devices 10 composed of the epitaxial structures 100 may be significantly reduced.

In the present embodiment, since the isolation area patterns are defined by the surrounding wall surface PWS of the epitaxial structure 100 of the light emitting device 10, the extending direction of the isolation area patterns is parallel to a sidewall surface of the surrounding wall surface PWS. That is, the included angle between the arrangement direction of the surface microstructures SMS and the extending direction of the isolation area patterns is the included angle between the arrangement direction of the surface microstructures SMS and the corresponding sidewall surface.

For example, the included angle between the first direction DR1 and the extending direction ED1 of the first isolation area patterns ISOP1 (that is, the included angle α1 between the first direction DR1 and the sidewall surface SWS2 defining the first isolation area patterns ISOP1) is between 65 degrees and between 85 degrees. The included angle between the second direction DR2 and the extending direction ED2 of the second isolation area patterns ISOP2 (that is, the included angle α2 between the second direction DR2 and the sidewall surface SWS1 defining the second isolation area patterns ISOP2) is between 65 degrees and between 85 degrees, preferably 75 degrees, for example. The included angle between the third direction DR3 and the extending direction ED2 of the second isolation area patterns ISOP2 (that is, the included angle α3 between the third direction DR3 and the sidewall surface SWS1 defining the second isolation area patterns ISOP2) is between 35 degrees and between 55 degrees, preferably 45 degrees, for example.

Alternatively, the included angle between the first direction DR1 and the extending direction ED2 of the second isolation area pattern ISOP2 may be between 5 degrees and 25 degrees, and the included angle between the second direction DR2 and the extending direction ED1 of the first isolation area pattern ISOP1 may be between 5 degrees and 25 degrees, preferably 15 degrees, for example. The included angle between the third direction DR3 and the extending direction ED1 of the first isolation area pattern ISOP1 may be between 35 degrees and 55 degrees, preferably 45 degrees, for example.

Via the included angle configuration relationship between the above arrangement directions and the isolation area patterns, it may be ensured that the cutting shape of the plurality of surface microstructure SMS on each of the epitaxial structures 100 at the cut section (i.e., the sidewall surface) of the epitaxial structure 100 exhibits irregularities in size or depth. In particular, here is the preferred angle design corresponding to different included angle ranges, that is, the middle value of the corresponding included angle range (such as 15 degrees, 45 degrees, or 75 degrees), to ensure that the profiles of all epitaxial structures 100 on all cut sections show irregularities, and the irregularities are not destroyed due to precision errors in the cutting process. Accordingly, the overall light emission uniformity of the plurality of light emitting devices 10 on the carrier board CS may be significantly improved.

In the above description, in the present embodiment, an included angle between the surrounding wall surface PWS of the epitaxial structure 100 and each of the extending directions may be provided by rotating the isolation area patterns, but the invention is not limited thereto. For example, in addition to rotating the isolation area pattern, a translation isolation area pattern may also be used to obtain more uniform surface microstructures SMS.

From another point of view, since the plurality of epitaxial structures 100 of the present embodiment are obtained by etching the epitaxial structure layer formed by the same process, the plurality of surface microstructures SMS of two adjacent epitaxial structures 100 that are separated by any isolation area pattern may be arranged in a plurality of rows along at least one arrangement direction. For example, the plurality of surface microstructures SMS on two epitaxial structures 100 that are separated by the first isolation area patterns ISOP1 and adjacent to each other (for example, the two epitaxial structures 100 in the upper right corner and the lower right corner or the upper left corner and the lower left corner in FIG. 5) may be arranged in a plurality of rows along the first direction DR1 or the third direction DR3. The plurality of surface microstructures SMS on two epitaxial structures 100 that are separated by the second isolation area patterns ISOP2 and adjacent to each other (for example, the two epitaxial structures 100 in the upper left corner and the upper right corner or the lower left corner and the lower right corner in FIG. 5) may be arranged in a plurality of rows along the second direction DR2 or the third direction DR3.

That is, even if two adjacent epitaxial structures 100 are separated by an isolation area pattern, some of the surface microstructures SMS on one of the epitaxial structures 100 and some of the surface microstructures SMS on the other epitaxial structure 100 may still be arranged collinearly along a virtual straight line crossing the isolation area pattern.

Based on the above, in the light emitting device substrate of an embodiment of the invention, none of the plurality of arrangement directions of the plurality of surface microstructures on the epitaxial structure of each of the light emitting devices is perpendicular to the surrounding wall surface of the epitaxial structure. Therefore, the light emission uniformity of the light emitting device and the overall light emission uniformity among the plurality of light emitting devices on the light emitting device substrate may be effectively improved.

What is claimed is:

1. A light emitting device, comprising:
an epitaxial structure having a light emitting surface and a surrounding wall surface, and the surrounding wall surface surrounds and is connected to the light emitting surface; and
a plurality of surface microstructures separately arranged on the light emitting surface along a plurality of directions, and the directions are not perpendicular to the surrounding wall surface.

2. The light emitting device of claim 1, wherein a sidewall of the surrounding wall surface reveals a first surface microstructure, a second surface microstructure, and a third surface microstructure of the surface microstructures, the first surface microstructure, the second surface microstructure, and the third surface microstructure respectively have a first maximum depth, a second maximum depth, and a third maximum depth along a normal direction of the light emitting surface, and the first maximum depth, the second maximum depth, and the third maximum depth are different from each other.

3. The light emitting device of claim 1, wherein an edge profile of the surrounding wall surface connected to the light emitting surface is rectangular.

4. The light emitting device of claim 1, wherein the surface microstructures are separately arranged on the light emitting surface in a hexagonal close packing manner.

5. The light emitting device of claim 4, wherein the surface microstructures are arranged along a first direction and a second direction respectively, and an included angle between the first direction and the second direction is 60 degrees.

6. The light emitting device of claim 1, wherein the light emitting surface defines an opening profile of each of the surface microstructures to be the same.

7. The light emitting device of claim 6, wherein maximum depths of the surface microstructures along a normal direction of the light emitting surface are all the same.

8. The light emitting device of claim 1, wherein the surface microstructures are arranged along a first direction, the surrounding wall surface has a plurality of sidewall surfaces, and an included angle between the first direction and any of the sidewall surfaces is between 5 degrees and 25 degrees, between 35 degrees and 55 degrees, or between 65 degrees and 85 degrees.

9. A light emitting device substrate, comprising:
a carrier board; and
a plurality of light emitting devices disposed on the carrier board, and each of the light emitting devices comprises:
an epitaxial structure having a light emitting surface; and
a plurality of surface microstructures separately arranged on the light emitting surface along a plurality of directions, wherein an orthographic projection of the plurality of epitaxial structures of the light emitting devices on the carrier board defines a plurality of isolation area patterns of the carrier board, and each of the directions is not perpendicular to an extending direction of each of the isolation area patterns.

10. The light emitting device substrate of claim 9, wherein the epitaxial structures further have a plurality of surrounding wall surfaces defining the isolation area patterns, and an edge profile of each of the surrounding wall surfaces connected to the light emitting surface is rectangular.

11. The light emitting device substrate of claim 9, wherein the epitaxial structures comprise a first and a second that are spaced apart by one of the isolation area patterns and adjacent to each other, and the surface microstructures of the first and the surface microstructures of the second are collinearly arranged in a plurality of rows along one of the directions.
